(19) United States
(12) Patent Application Publication
(10) Pub. No.: US 2021/0408307 A1
(43) Pub. Date: Dec. 30, 2021

(54) METHOD FOR PRODUCING MOSAIC SOLAR CELL ASSEMBLIES

(71) Applicant: SolAero Technologies Corp., Albuquerque, NM (US)

(72) Inventors: Daniel Aiken, Cedar Crest, NM (US); Daniel Derkacs, Albuquerque, NM (US); Claiborne McPheeters, Albuquerque, NM (US)

(73) Assignee: SolAero Technologies Corp., Albuquerque, NM (US)

(21) Appl. No.: 17/170,440

(22) Filed: Feb. 8, 2021

Related U.S. Application Data
(63) Continuation-in-part of application No. 15/081,123, filed on Mar. 25, 2016, now abandoned.
Application No. 15/081,123 is a continuation-in-part of application No. 15/900,385, filed on Feb. 20, 2018, now abandoned.
Application No. 15/900,385 is a continuation-in-part of application No. 16/109,174, filed on Aug. 22, 2018, now abandoned.
Application No. 16/109,174 is a continuation-in-part of application No. 16/951,617, filed on Nov. 18, 2020, now abandoned.
Application No. 16/951,617 is a division of application No. 16/410,904, filed on May 13, 2019, now abandoned.

(51) Int. Cl. H01L 31/0352; H01L 31/18; H01L 31/0735; H01L 31/0475

(52) U.S. Cl. CPC H01L 31/035281; H01L 31/0475; H01L 31/0735; H01L 31/184

(57) ABSTRACT

A method for producing a mosaic solar cell assembly, comprising the steps of singulating a III-V compound semiconductor solar cell wafer into four identical discrete solar cell mosaic elements each substantially shaped as a quadrant of a circle, comprising a first and second solar cell mosaic element having one curved edge in the shape of an arc of the circumference of the circular wafer from which the element was singulated, and a single straight edge, rearranging and positioning two of the mosaic elements into a substantially rectangular mosaic assembly; providing a metal interconnect between each of the mosaic elements along one edge of the assembly so that the mosaic elements may be electrically connected to an adjacent mosaic assembly; and optionally bonding the cover glass support to the top of the mosaic assembly.

### REFERENCE TO RELATED APPLICATIONS

The present application is a continuation-in-part of U.S. patent application Ser. No. 16/951,617 filed Nov. 18, 2020, which was a divisional of U.S. patent application Ser. No. 16/410,904 filed May 13, 2019, which is a continuation-in-part of U.S. patent application Ser. No. 15/081,123 filed Mar. 25, 2016, Ser. No. 15/900,385, filed Feb. 20, 2018; and Ser. No. 16/109,174 filed Aug. 22, 2018.

This application is related to U.S. patent application Ser. No. 14/498,071 filed Sep. 26, 2014, and its divisional application Ser. No. 15/014,667 filed Feb. 6, 2016.

This application is also related to U.S. patent application Ser. No. 14/514,883 filed Oct. 14, 2014, which is the parent application of Ser. No. 15/900,385.

This application is also related to U.S. patent application Ser. No. 14/151,236 filed Jan. 9, 2014.

This application is also related to U.S. patent application Ser. No. 29/505,800 filed Feb. 17, 2016, now U.S. Pat. No. D784,253, and Ser. No. 29/650,015 filed Jun. 4, 2018, now U.S. Pat. No. D861,591.

All of the above applications are hereby incorporated by reference.

### BACKGROUND OF THE DISCLOSURE

### 1. Field of the Disclosure

The disclosure relates to the field of photovoltaic power devices, and more particularly integral mosaic assemblies or CICs of discrete solar cell mosaic elements.

### 2. Description of the Related Art

Photovoltaic devices, such as photovoltaic modules or CIC (solar Cell+Interconnects+Cover glass) assemblies, comprise one or more individual solar cells arranged to produce electric power in response to irradiation by solar light. Sometimes, the individual solar cells are rectangular, often square. Photovoltaic modules, arrays and devices including one or more solar cells may also be substantially rectangular, for example, based on an array of individual solar cells. Arrays of substantially circular solar cells are known to involve the drawback of inefficient use of the surface on which the solar cells are mounted, due to space that is not covered by the circular solar cells that is left between adjacent solar cells due to their circular configuration (cf. U.S. Pat. Nos. 4,235,643 and 4,321,417).

However, solar cells are often produced from circular or substantially circular wafers. For example, solar cells for space applications are typically multi-junction solar cells grown on substantially circular wafers. These circular wafers are typically 100 mm or 150 mm diameter wafers. However, as explained above, for assembly into a solar cell module (henceforth, also referred to as a solar cell assembly), substantially circular solar cells, which can be produced from substantially circular wafers to minimize wasting wafer material and, therefore, minimize solar cell cost, are often not the best option, due to their low array fill factor, which increases the overall cost of the photovoltaic array or panel and implies an inefficient use of available space. Therefore, the circular wafers are often divided into other form factors to make smaller solar cells. The preferable form factor for a solar cell for space is a rectangle, such as a square, which allows for the area of a rectangular panel consisting of an array of solar cells to be filled 100% (henceforth, that situation is referred to as a “fill factor” of 100%), assuming that there is no space between the adjacent rectangular solar cells. However, when a single circular wafer is divided into a single rectangle, the wafer utilization is low. This results in waste in the usable wafer area. Since a rectangular solar cell can be placed side by side with other rectangular solar cells obtained from other wafers, thereby providing for efficient use of the surface on which the solar cells are placed (i.e., a high fill factor): a large W/m² ratio can be obtained, which depending on the substrate may also imply a high W/kg ratio, of great importance for space applications. That is, closely packed solar cells without any space between the adjacent solar cells is generally preferred, and especially for applications in which W/m² and/or W/kg are important aspects to consider. This includes space applications, such as solar power devices for satellites or space vehicles.

The assembly of individual solar cells together with electrical interconnects and the cover glass form a so-called “CIC” (Cell-Interconnect-Cover glass) assembly, which are then typically electrically connected to form an array of series-connected solar cells. The solar cells used in many arrays often have a substantial size; for example, in the case of the single standard substantially “square” solar cell trimmed from a 100 mm wafer with cropped corners, the solar cell can have a side length of seven cm or more.

### SUMMARY OF THE DISCLOSURE

### Objects of the Disclosure

It is an object of the present disclosure to provide a method of fabricating a mosaic solar cell assembly by singulating a wafer into mosaic elements which maximizes both the utilization of the wafer area from which the mosaic elements are scribed, and the packing factor of the rearranged mosaic elements over a rectangular reference template.

### Features of the Disclosure

All ranges of numerical parameters set forth in this disclosure are to be understood to encompass any and all subranges or “intermediate generalizations” subsumed herein. For example, a stated range of “1.0 to 2.0 eV” for a band gap value should be considered to include any and all subranges beginning with a minimum value of 1.0 eV or more and ending with a maximum value of 2.0 eV or less, e.g., 1.0 to 1.6, or 1.3 to 1.4, or 1.5 to 1.9 eV.

The present disclosure is directed to the method of fabricating a mosaic solar cell assembly by scribing and singulating a substantially circular semiconductor solar cell wafer into a plurality of discrete polygonal or “mosaic” solar cells elements, and then rearranging, positioning and electrically connecting the elements in parallel as a closely packed “mosaic” solar cell assembly over the surface of a rectangularly shaped reference template. By utilizing a small number of mosaic elements, thereby minimizing the number and production cost of the placement of interconnect elements between the discrete mosaic elements, one can maximize both the area coverage of the solar cell elements over the template, and the utilization of the wafer surface area of the original solar cell wafer. Since the mosaic assembly has more active area over the surface of the square template than a single cropped-corner wafer would have, it provides greater efficiency in terms of the power density in W/m², or power per unit mass in W/kg, than previous approaches.

Briefly, and in general terms, the present disclosure provides a method for producing a mosaic solar cell assembly and the assembly so produced, comprising the steps of providing a circular solar cell wafer; chamfering at least one diametrically opposed pair of sides of the wafer along two spaced apart portions of the circumference; cutting the wafer into four quadrants to form mosaic elements; rearranging and positioning at least two mosaic elements adjacent to one another into a substantially rectangular mosaic assembly; providing a metal interconnect to each of the mosaic elements so that the mosaic elements may be electrically connected to an adjacent mosaic assembly; providing a cover glass support; and bonding the cover glass support to the top of the mosaic assembly.

### BRIEF DESCRIPTION OF THE DRAWINGS

To complete the description and in order to provide for a better understanding of the disclosure, a set of drawings is provided. Said drawings form an integral part of the description and illustrate embodiments of the disclosure, which should not be interpreted as restricting the scope of the disclosure, but just as examples of how the disclosure can be carried out. The drawings comprise the following figures:

FIG. 1A illustrates a circular solar cell wafer from which four mosaic solar cells according to a first embodiment the present disclosure are scribed;

FIG. 1B illustrates a CIC assembly according to a first embodiment of the present disclosure utilizing grouping of two of the solar cells of FIG. 1A;

FIG. 1C is a cross-sectional view of the CIC assembly of FIG. 1B;

FIG. 2A illustrates a circular solar cell wafer from which four solar cells according to a second embodiment of the present disclosure are scribed;

FIG. 2B illustrates one of the mosaic elements scribed from the wafer of FIG. 2A;

FIG. 2C illustrates a CIC assembly according to a second embodiment of the present disclosure utilizing a grouping of two of the four solar cells of FIG. 2A;

FIG. 2D is a cross-sectional view of the CIC assembly of FIG. 2C; and

FIG. 3 illustrates a portion of a solar cell panel depicting two interconnected CIC assemblies according to the present disclosure.

### DESCRIPTION OF THE PREFERRED EMBODIMENT

Details of the present invention will now be described including exemplary aspects and embodiments thereof. Referring to the drawings and the following description, like reference numbers are used to identify like or functionally similar elements, and are intended to illustrate major features of exemplary embodiments in a highly simplified diagrammatic manner. Moreover, the drawings are not intended to depict every feature of the actual embodiment nor the relative dimensions of the depicted elements, and are not drawn to scale.

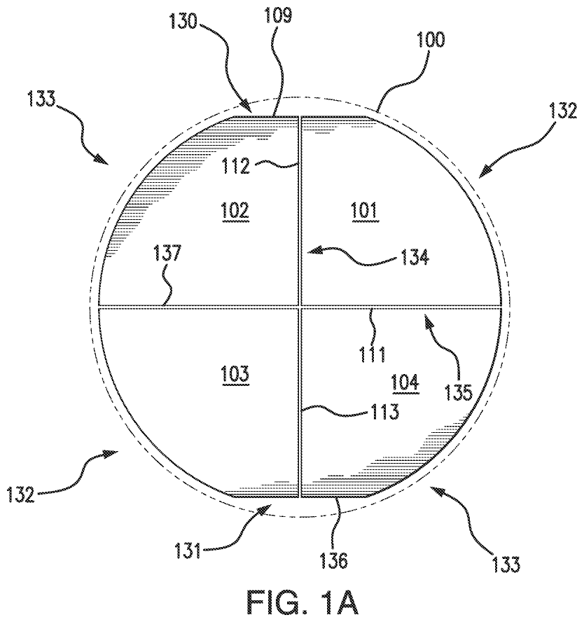

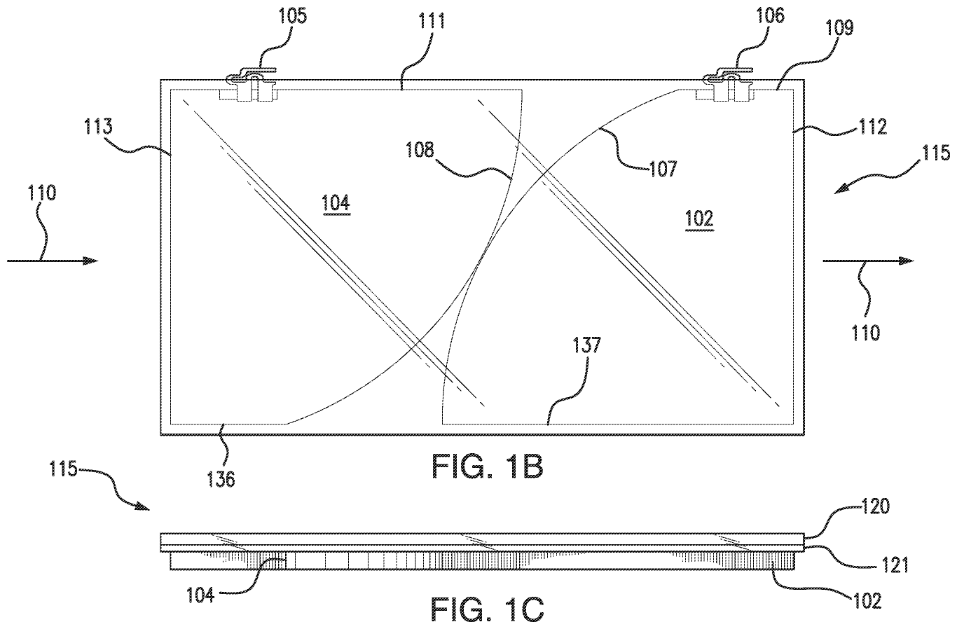

FIG. 1A illustrates a circular solar cell wafer 100 from which four mosaic solar cell elements 101, 102, 103 and 104 according to the present disclosure are singulated or scribed. In the depicted embodiment, the wafer 100 is a four-inch (or 100 mm diameter) wafer, and the area of each of the mosaic elements 101, 102, 103 and 104 are 18 to 20 cm².

The sequence of steps for fabricating the CIC or mosaic solar cell assembly comprises the steps of: providing a circular III-V compound semiconductor solar cell wafer 100; chamfering at least one diametrically opposed pair of sides 110 and 111 of the wafer along two spaced apart portions of the circumference; and cutting the wafer into four quadrants 101, 102, 103 and 104 to form four mosaic elements. The four mosaic elements are separated, and two such elements 102, 104 are rearranged and positioned adjacent to one another into a substantially rectangular mosaic assembly 115 shown in FIG. 1B. A discrete metal interconnect 105, 106 is bonded to an edge of each of the mosaic elements so as to form an electrical contact so that the mosaic elements may be electrically connected to an adjacent mosaic assembly.

FIG. 1B illustrates a portion of the CIC assembly 108 according to a first embodiment of the present disclosure utilizing the two of the mosaic solar cell elements of FIG. 1A arranged into a rectangular reference template.

As shown in FIG. 1B, the two mosaic elements 102, 104 are arranged directly adjacent to one another along a first axis 110, so that the first and second curved edges 107, 108 of each of the two mosaic elements are touching and adjacent one another and form a single row of mosaic elements, each of the two mosaic elements being aligned so as to have substantially the same height in a direction perpendicular to the first axis 110, the first mosaic element having a first edge 109 parallel to the first axis and the second mosaic element having a second edge 111 parallel to the first axis, the third 112 and fourth 113 edges being aligned in a direction perpendicular to the first axis, so as to form a substantially rectangular solar cell assembly, with the first edge 109 of the first mosaic element forming a portion of one elongated side of the rectangular solar cell assembly 115, and the second edge 111 of the second mosaic element being colinear with the first edge 109 and forming a portion of the elongated side of the rectangular solar cell assembly.

Following the attachment of the interconnects 105, 106, a cover glass support 120 is bonded to the top of the mosaic elements 102, 104 by a bonding material 121 to form the mosaic assembly 115.

FIG. 1C is a cross-sectional view of the CIC assembly 115 of FIG. 1B. In particular, the cover glass support 120 and bonding material 121 is illustrated.

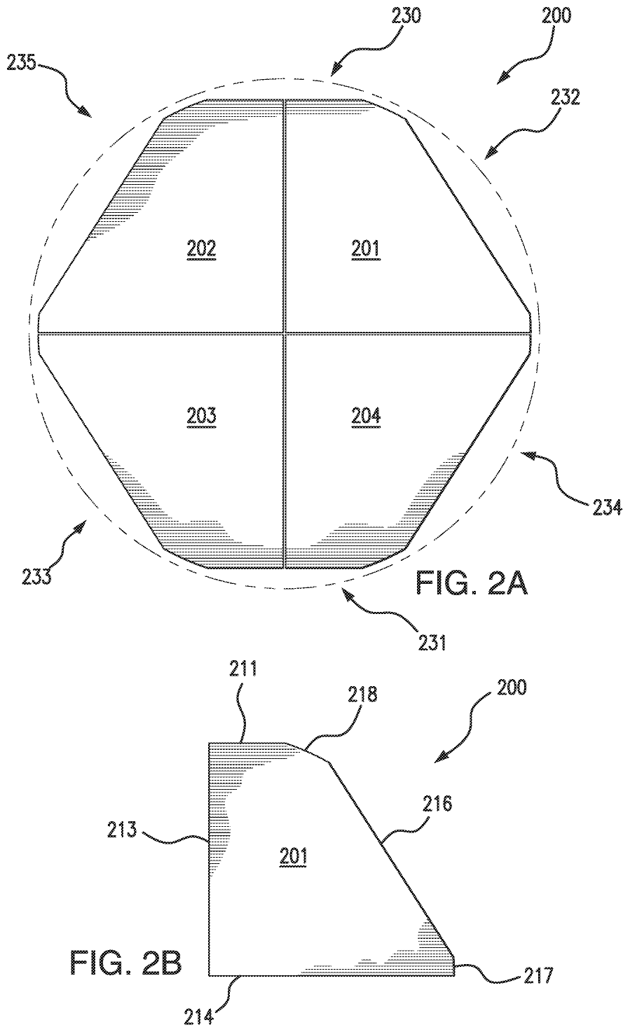

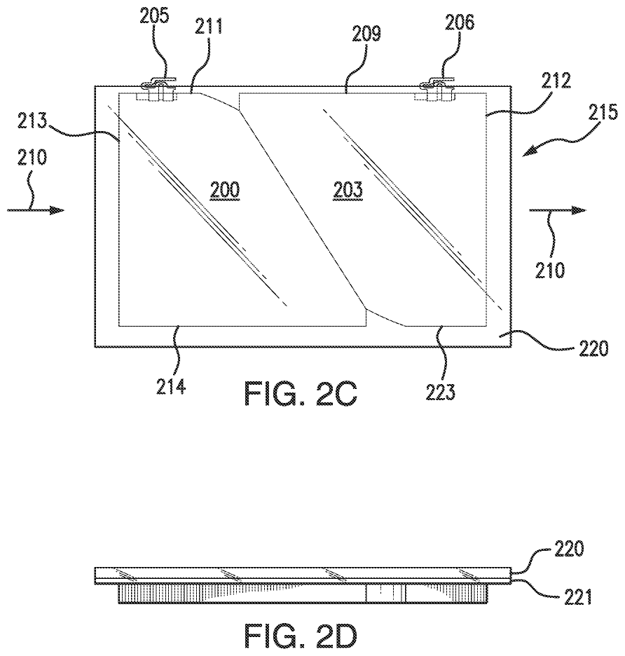

FIG. 2A illustrates a circular solar cell wafer 200 in a second embodiment of the present disclosure from which four mosaic solar cell elements 201, 202, 203 and 204 are scribed. For a four-inch (or 100 mm wafer) the mosaic solar cell elements each having an area of approximately 15 cm².

FIG. 2B illustrates one of the mosaic elements 201 to more particularly point out the peripheral edges: a first straight line portion 211 arising from chamfer cut 230, a second straight line portion 216 arising from chamfer cut 232, and a first portion 218 of the circumference disposed between straight line portions 211 and 216. The singulation cuts 213 and 214 form two peripheral side boundaries, and a second portion of the circumference 217 is disposed between segments 214 and 216.

The sequence of steps for fabricating the CIC or mosaic solar cell assembly comprises the steps of: providing a circular solar cell wafer 200; chamfering three diametrically opposed pair of sides 230/231, 232/233, and 234/235 of the wafer along spaced apart portions of the circumference. The wafer is then cut or singulated into four quadrants 201, 202, 203 and 204 to form four discrete mosaic elements. One such element is depicted in FIG. 2B. Two of the mosaic elements are then rearranged and positioned adjacent to one another into a substantially rectangular mosaic assembly 215 shown in FIG. 2C.

The next step is to provide a metal interconnect 205 and 206 to each of the mosaic elements 205 and 206 so that the mosaic elements may be electrically connected to an adjacent mosaic assembly; and bonding the cover glass support 220 to the top of the mosaic assembly.

FIG. 2C illustrates a portion of a CIC assembly 215 according to a second embodiment of the present disclosure utilizing only two (200 and 203) of the mosaic solar cell elements of FIG. 2A. Individual interconnects 205 and 206 may be provided along the upper edge depicted in the Figure making electrical contact with the top surface of each of the mosaic elements 200 and 203 respectively.

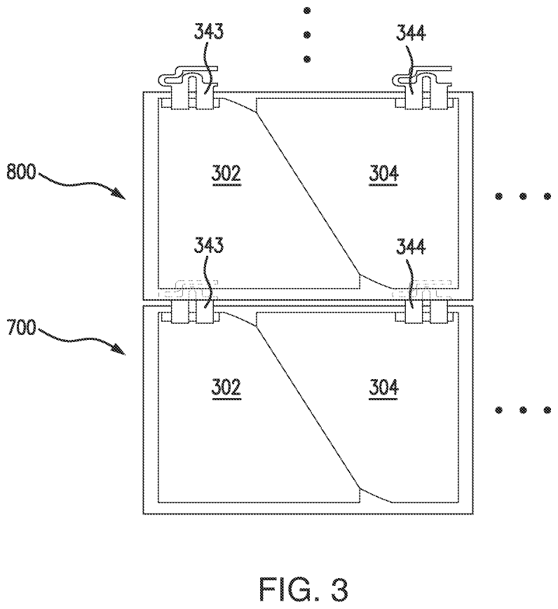

FIG. 3 illustrates the configuration of a portion of a solar cell panel in which the solar cell assemblies according to either the first or the second embodiment of the present disclosure are electrically coupled to one another to form a series electrical circuit. The figure depicts a first CIC assembly 700 and a second CIC assembly 800 on such a panel; wherein the one elongated side of the first solar cell assembly is disposed directly adjacent to the lower elongated side of a second solar cell assembly so that the first 343 and second 344 conductive interconnects on the first CIC assembly 700 couples the first rectangular solar cell assembly 700 in electrical series with the second solar cell assembly 800.

The first and second solar cell assemblies are aligned so that the third 213 and fourth 214 edges of the first solar cell assembly 700 align with the corresponding third 213 and fourth 214 edges of the second solar cell assembly 800, as depicted in the Figure. In the illustrated interconnects, the top surface of the mosaic solar cells in the first assembly 700 representing a first conductivity type is coupled with the bottom or back surface of the mosaic solar cells in the second assembly 800.

It has been found that the use of solar cells shaped substantially as quadrants of a circle is a simple and efficient solution, since the quadrants can fit into a rectangular unit cell with a fill factor of about 90% or greater, that is, with a rather high fill factor.

The following clauses summarize the features descriptive of the method for producing a solar cell assembly in the embodiment of FIGS. 1A through 1C:

### CLAUSES

1. A method for producing a solar cell assembly, comprising the steps of:

providing at least one III-V compound semiconductor circular solar cell wafer 100;

chamfering each wafer along its circumferential edge into two diametrically opposed portions (130, 131) of the circumference of the wafer so as to produce a chamfered wafer having a circumference comprising at least first and second diametrically opposed curved edges (132, 133) representing the circumferential edge of the wafer, the chamfered portion being sized so as to minimize the loss of usable wafer area; and

singulating each chamfered wafer by two orthogonal straight lines (134, 135) extending through the center of the wafer and dividing the wafer into four quadrants to form a set of four discrete mosaic elements (101, 102, 103, 104).

2. A method as defined in clause 1, further comprising arranging only two (102, 104) of the mosaic elements directly adjacent to one another along a first axis (110), so that the first and second curved edges (107, 108) of each of the two mosaic elements are touching and adjacent one another and form a single row of mosaic elements, each of the two mosaic elements are being aligned so as to have substantially the same height (112, 113) in a direction perpendicular to the first axis, the first mosaic element (102) having a first edge (109) parallel to the first axis and the second mosaic element (104) having a second edge (111) parallel to the first axis, the third and fourth edges (112, 113) being aligned in a direction perpendicular to the first axis, so as to form a substantially rectangular solar cell assembly, with the first edge (109) of the first mosaic element (102) forming a portion of one elongated side of the rectangular solar cell assembly, and the second edge (111) of the second mosaic element (104) being colinear with the first edge (109) and forming a portion of the elongated side of the rectangular solar cell assembly.
3. A method as defined in clause 2, further comprising mounting a single cover glass (120) disposed over both of the first and second mosaic elements.
4. A method as defined in any of the preceding clauses, further comprising mounting a first discrete conductive interconnect (105) mounted on the first edge (109) of the first mosaic element (102) and a second discrete conductive interconnect (105) mounted on the edge (111) of the second mosaic element.
5. A method as defined in any of the preceding clauses, wherein the chamfered wafer includes two diametrically opposed and parallel straight line segments (130, 131) which are parallel to an axial line through the center of the wafer and which form the chamfered edge (136, 109) of each of the first and second mosaic elements.
6. A method as defined in clause 5, wherein the two diametrically opposed straight line segments (130, 131) have the same length.
7. A method as defined in any of the preceding clauses, wherein the one elongated side of the first solar cell assembly is disposed directly adjacent to the lower elongated side of a second solar cell assembly so that the conductive interconnect couples the first rectangular solar cell assembly in electrical series with the second solar cell assembly.
8. A method as defined in any of the preceding clauses, wherein the first and second solar cell assemblies are aligned so that the third and fourth edges of the first solar cell assembly align with the corresponding third and fourth edges of the second solar cell assembly.
9. A method as defined in any of the preceding clauses, wherein the chamfering of each circular cell wafer achieves greater than 90% wafer utilization.
10. A method as defined in any one more of clauses 7, 8 or 9, wherein the alignment of the first and second solar cell assemblies achieves a fill factor of 100% of a rectangular surface.
11. A method as defined in any one or more of clauses 7, 8, 9 or 10, wherein each of the first and second solar cell assemblies are identical is size and shape.
12. A method for producing a solar cell assembly, comprising the steps of:

providing at least one III-V compound semiconductor circular solar cell wafer;

chamfering each wafer along its circumferential edge into two diametrically opposed portions of the circumference of the wafer and sized so as to produce a chamfered wafer having a circumference comprising at least first and second diametrically opposed straight edges along the circumferential edge of the wafer and sized so as to minimize the loss of usable wafer area;

chamfering each wafer along its circumferential edge into a third and a fourth additional pair of diametrically opposed portions of the circumference of the wafer to produce a chamfered wafer including a first pair of third and fourth diametrically opposed chamfered straight edges, and a second pair of fifth and sixth diametrically opposed chamfered straight edges along the circumferential edge of the wafer; and

singulating each chamfered wafer by a first and second straight lines orthogonal to each other extending through the center of the wafer and dividing the wafer into four quadrants to form a set of four discrete mosaic elements, the first straight line bisecting the first and second diametrically opposed straight edge, and forming a seventh edge of each mosaic element, and the second straight line forming an eighth edge of each mosaic element.

13. A method as defined in clause 12, wherein the angle between the second straight line extending through the center of the wafer and the third chamfered straight edge is between 45 and 75 degrees.
14. A method as defined in any one or more of clauses 12 or 13, wherein the third, fourth, fifth and sixth straight line edges have the same length.
15. A method as defined in any one or more of clauses 12, 13 or 14, wherein the length of the first and second diametrically opposed straight edges is less than the length of the third, fourth, fifth and sixth straight line edges.
16. A method as defined in any one or more of clauses 12, 13, 14 or 15, wherein the discrete mosaic elements are identical in size and shape.
17. A method as defined in clauses 12, 13, 14, 15 or 16, further comprising arranging only a first and a second of the mosaic elements directly adjacent to one another along a first axis, so that the third and fourth chamfered straight edges of each of the first and second mosaic elements are touching and adjacent one another and form a single row of mosaic elements, each of the first and second mosaic elements being aligned so as to have substantially the same height in a direction perpendicular to the first axis.
18. The method as defined in clause 17, wherein the first mosaic element having a first edge parallel to the first axis and the second mosaic element having a second edge parallel to the first axis, the third and fourth edges being aligned in a direction perpendicular to the first axis, so as to form a substantially rectangular solar cell assembly, with the first edge of the first mosaic element forming a portion of a first elongated side of the rectangular solar cell assembly, and the second edge of the second mosaic element being colinear with the first edge and forming a portion of the first elongated side of the rectangular solar cell assembly.
19. The method as defined in any one or more of clauses 17 or 18, wherein the first mosaic element having its seventh edge orthogonal to the first axis and the second mosaic element having its eighth edge orthogonal to the first axis, the seventh and eighth edges being aligned so as to form a substantially rectangular solar cell assembly, and the eighth edge of the second mosaic element forming the second side of the rectangular solar cell assembly opposite to the first side.
20. A method as defined in any one or more of clauses 17, 18 or 19, wherein the first and second mosaic elements are mounted on a cover glass support forming a rectangular reference template with each mosaic element having the same height and arranged serially along the length of the rectangular template.
21. A method as defined in any one or more of clauses 17 or 18, wherein the one elongated side of the first solar cell assembly is disposed directly adjacent to the lower elongated side of a second solar cell assembly so that the first and second conductive interconnects couples the first rectangular solar cell assembly in electrical series with the second solar cell assembly.
22. A method as defined in any one or more of clauses 17-21, wherein the first and second solar cell assemblies are aligned so that the third and fourth edges of the second solar cell assembly align with the corresponding third and fourth edges of the second solar cell assembly.
23. A method as defined in any of the preceding clauses, wherein the alignment of the first and second solar cell assemblies achieves a fill factor of 100% of rectangular surface.
24. A method as defined in any of the preceding clauses, wherein each of the first and second solar cell assemblies are identical in size and shape.
25. A method as defined in any one or more the preceding clauses, wherein the chamfering of each circular solar cell wafer achieves greater than 90% wafer utilization.
26. A solar cell assembly, comprising:

a III-V compound semiconductor circular solar cell wafer, chamfering along its circumferential edge so as to produce a chamfered wafer having a circumference comprising

(i) at least first and second diametrically opposed straight edges along the circumferential edge of the wafer and sized so as to minimize the loss of usable wafer area; and

(ii) a first pair of third and fourth diametrically opposed chamfered straight edges, and

wherein each chamfered wafer is singulated by a first and a second straight lines

(iii) a second pair of fifth and sixth diametrically opposed chamfered straight edges along the circumferential edge of the wafer; and

wherein each chamfered wafer is singulated by a first and a second straight lines orthogonal to each other extending through the center of the wafer and dividing the wafer into four quadrants to form a set of four discrete mosaic elements, the first straight line bisecting the first and second diametrically opposed straight edge, and forming a seventh edge of each mosaic element, and the second straight line forming an eighth edge of each mosaic element.

27. A solar cell assembly as defined in clause 26, wherein the angle between the second straight line extending through the center of the wafer and the third chamfered straight edge is between 45 and 75 degrees.
28. A solar cell assembly as defined in any one or more of clauses 26 and 27, wherein the third, fourth, fifth and sixth straight line edges have the same length.
29. A solar cell assembly as defined in any one or more of clauses 26, 27, and 28, wherein the length of the first and second diametrically opposed straight edges is less than the length of the third, fourth, fifth and sixth straight line edges, and wherein the discrete mosaic elements are identical in size and shape.
30. A solar cell assembly as defined in any one or more of clauses 26, 27, 28, and 29, wherein only a first and a second of the mosaic elements are arranged directly adjacent to one another along a first axis, so that the third and fourth chamfered straight edges of each of the first and second mosaic elements are touching and adjacent one another and form a single row of mosaic elements, each of the first and second mosaic elements being aligned so as to have substantially the same height in a direction perpendicular to the first axis.
31. In another aspect, the present disclosure provides a solar cell assembly comprising:

a first mosaic element and a second mosaic element each singulated as a quadrant of a circle cut from III-V compound semiconductor circular solar cell wafer;

the first mosaic element being chamfered from a circular wafer along a portion of the wafer's circumferential edge and forming a first straight chamfered edge of the first mosaic element which is sized so as to minimize the loss of usable wafer area; the first mosaic element having a second straight edge having a length equal to the radius of the circular wafer adjacent to the other end of the circumferential edge, and a third straight edge adjacent to and orthogonal to the first straight chamfered edge;

the second mosaic element being chamfered from a circular wafer along a portion of the wafer's circumferential edge and forming a first straight chamfered edge of the first mosaic element which is sized so as to minimize the loss of usable wafer area; the second mosaic element having a second straight edge having a length equal to the radius of the circular wafer adjacent to the other end of the circumferential edge, and a third straight edge adjacent to and orthogonal to the first chamfered edge;

the first and second mosaic elements being arranged directly adjacent to one another along a first axis, so that the first and second curved edges of each of the two mosaic elements are touching and adjacent one another and form a single row of mosaic elements, each of the two mosaic element being aligned so as to have substantially the same height in a direction perpendicular to the first axis, the first mosaic element having a first edge parallel to the first axis and the second mosaic element having a second edge parallel to the first axis, so as to form a substantially rectangular solar cell assembly, with the first edge of the mosaic element forming a portion of one elongated side of the rectangular solar cell assembly, and the second edge of the second mosaic element forming a portion of the opposite elongated side of the rectangular solar cell assembly.

32. In another aspect, the present disclosure provides a solar cell assembly, comprising:

a III-V compound semiconductor circular solar cell wafer, chamfering along its circumferential edge so as to produce a chamfered wafer having a circumference comprising

(i) at least first and second diametrically opposed straight edges along the circumferential edge of the wafer and sized so as to minimize the loss of usable wafer area; and

(ii) a first pair of third and fourth diametrically opposed chamfered straight edges, and wherein each chamfered wafer is singulated by a first and a second straight lines

(iii) second pair of fifth and sixth diametrically opposed chamfered straight edges along the circumferential edge of the wafer; and

wherein each chamfered wafer is singulated by a first and a second straight lines orthogonal to each other extending through the center of the wafer and dividing the wafer into four quadrants to form a set of four discrete mosaic elements, the first straight line bisecting the first and second diametrically opposed straight edge, and forming a seventh edge of each mosaic element, and the second straight line forming an eighth edge of each mosaic element.

33. A solar cell assembly as defined in clause 32, wherein the angle between the second straight line extending through the center of the wafer and the third chamfered straight edge is between 45 and 75 degrees.
34. A solar cell assembly as defined in any one or more of clauses 32 and 33, wherein the third, fourth fifth and sixth straight line edges have the same length.
35. A solar cell assembly as defined in any one or more of clauses 32, 33 and 34, wherein the length of the first and second diametrically opposed straight edges is less than the length of the third, fourth, fifth, and sixth straight line edges, and wherein the discrete mosaic elements are identical is size and shape.
36. A solar cell assembly as defined in any one or more of clauses 32, 33, 34 or 35, further comprising arranging only a first and a second of the mosaic elements directly adjacent to one another along a first axis, so that the third and fourth chamfered straight edges of each of the first and second mosaic elements are touching and adjacent one another and form a single row of mosaic elements, each of the first and second mosaic elements being aligned so as to have substantially the same height in a direction perpendicular to the first axis.
37. In another aspect, the present disclosure provides a solar assembly comprising:

a first mosaic element and a second mosaic element each singulated as a quadrant of a circle cut from III-V compound semiconductor circular solar cell wafer;

the first mosaic element being chamfered from a circular wafer along a portion of the wafer's circumferential edge and forming a first straight chamfered edge of the first mosaic element which is sized so as to minimize the loss of usable wafer area; the first mosaic element having a second straight edge having a length equal to the radius of the circular wafer adjacent to the other end of the circumferential edge, and a third straight edge adjacent to and orthogonal to the first straight chamfered edge;

the second mosaic element being chamfered from a circular wafer along a portion of the wafer's circumferential edge and forming a first straight chamfered edge of the first mosaic element which is sized so as to minimize the loss of usable wafer area; the second mosaic element having a second straight edge having a length equal to the radius of the circular wafer adjacent to the other end of the circumferential edge, and a third straight edge adjacent to and orthogonal to the first chamfered edge;

the first and second mosaic elements being arranged directly adjacent to one another along a first axis, so that the first and second curved edges of each of the two mosaic elements are touching and adjacent one another and form a single row of mosaic elements, each of the two mosaic element being aligned so as to have substantially the same height in a direction perpendicular to the first axis, the first mosaic element having a first edge parallel to the first axis and the second mosaic element having a second edge parallel to the first axis, so as to form a substantially rectangular solar cell assembly, with the first edge of the mosaic element forming a portion of one elongated side of the rectangular solar cell assembly, and the second edge of the second mosaic element forming a portion of the opposite elongated side of the rectangular solar cell assembly.

1. A method for producing a solar cell assembly, comprising the steps of:
providing at least one III-V compound semiconductor circular solar cell wafer;
chamfering each wafer along its circumferential edge into two diametrically opposed portions of the circumference of the wafer so as to produce a chamfered wafer having a circumference comprising at least first and second diametrically opposed straight edges along the circumferential edge of the wafer and sized so as to minimize the loss of usable wafer area;
chamfering each wafer along its circumferential edge into a third and a fourth additional pair of diametrically opposed portions of the circumference of the wafer spaced apart from each other to produce a chamfered wafer including a first pair of third and fourth diametrically opposed chamfered straight edges, and a second pair of fifth and sixth diametrically opposed chamfered straight edges along the circumferential edge of the wafer; and
singulating each chamfered wafer by a first and second straight lines which are orthogonal to each other extending through the center of the wafer and dividing the wafer into four quadrants to form a set of four discrete mosaic elements, the first straight line bisecting the first and second diametrically opposed straight edges, and forming a seventh edge of each mosaic element, and the second straight line forming an eighth edge of each mosaic element.

2. A method as defined in claim 1, wherein the angle between the second straight line extending through the center of the wafer and the third chamfered straight edge is in the range between 45 and 75 degrees.

3. A method as defined in claim 1, wherein the third, fourth, fifth and sixth straight line edges have the same length.

4. A method as defined in claim 1, wherein the length of the first and second diametrically opposed straight edges is less than the length of the third, fourth, fifth and sixth straight line edges.

5. A method as defined in claim 1, wherein the discrete mosaic elements are identical in size and shape.

6. A method as defined in claim 1, further comprising arranging only a first and a second of the mosaic elements directly adjacent to one another along a first axis, so that the third and fourth chamfered straight edges of each of the first and second mosaic elements are touching and adjacent one another and form a single row of mosaic elements, each of the first and second mosaic elements being aligned so as to have substantially the same height in a direction perpendicular to the first axis.

7. The method as defined in claim 6, wherein the first mosaic element has a first edge parallel to the first axis and the second mosaic element has a second edge parallel to the first axis, the third and fourth edges being aligned in a direction perpendicular to the first axis, so as to form a substantially rectangular solar cell assembly, with the first edge of the first mosaic element forming a portion of a first elongated side of the rectangular solar cell assembly, and the second edge of the second mosaic element being colinear with the first edge and forming a portion of the first elongated side of the rectangular solar cell assembly.

8. The method as defined in claim 6, wherein the first mosaic element having its seventh edge orthogonal to the first axis and the second mosaic element having its eighth edge orthogonal to the first axis, the seventh and eighth edges being aligned so as to form a substantially rectangular solar cell assembly, with the seventh edge of the first mosaic element forming one side of the rectangular solar cell assembly, and the eighth edge of the second mosaic element forming the second side of the rectangular solar cell assembly opposite to the first side.

9. A method as defined in claim 6, wherein the first and second mosaic elements are mounted on a cover glass support forming a rectangular reference template with each mosaic element having the same height and arranged serially along the length of the rectangular template.

10. A method as defined in claim 9, wherein the one elongated side of the first solar cell assembly is disposed directly adjacent to the lower elongated side of a second solar cell assembly so that the first and second conductive interconnects couples the first rectangular solar cell assembly in electrical series with the second solar cell assembly.

11. A method as defined in claim 1, wherein the chamfering of each circular solar cell wafer achieves greater than 90% wafer utilization.

12. A method as defined in claim 10, wherein the first and second solar cell assemblies are aligned so that the third and fourth edges of the second solar cell assembly align with the corresponding third and fourth edges of the second solar cell assembly.

13. A method as defined in claim 10, wherein the alignment of the first and second solar cell assemblies achieves a fill factor of 100% of a rectangular surface.

14. A method as defined in claim 10, wherein each of the first and second solar cell assemblies are identical in size and shape.

15. A solar cell assembly, comprising:
a III-V compound semiconductor circular solar cell wafer, chamfering along its circumferential edge so as to produce a chamfered wafer having a circumference comprising
(i) at least first and second diametrically opposed straight edges along the circumferential edge of the wafer and sized so as to minimize the loss of usable wafer area; and
(ii) a first pair of third and fourth diametrically opposed chamfered straight edges, and wherein each chamfered wafer is singulated by a first and a second straight lines
(iii) a second pair of fifth and sixth diametrically opposed chamfered straight edges along the circumferential edge of the wafer; and
wherein each chamfered wafer is singulated by a first and a second straight lines orthogonal to each other extending through the center of the wafer and dividing the wafer into four quadrants to form a set of four discrete mosaic elements, the first straight line bisecting the first and second diametrically opposed straight edge, and forming a seventh edge of each mosaic element, and the second straight line forming an eighth edge of each mosaic element.

16. A solar cell assembly as defined in claim 15, wherein the angle between the second straight line extending through the center of the wafer and the third chamfered straight edge is between 45 and 75 degrees.

17. A solar cell assembly as defined in claim 15, wherein the third, fourth, fifth and sixth straight line edges have the same length.

18. A solar cell assembly as defined in claim 15, wherein the length of the first and second diametrically opposed straight edges is less than the length of the third, fourth, fifth and sixth straight line edges, and wherein the discrete mosaic elements are identical in size and shape.

19. A solar cell assembly as defined in claim 15, further comprising arranging only a first and a second of the mosaic elements directly adjacent to one another along a first axis, so that the third and fourth chamfered straight edges of each of the first and second mosaic elements are touching and adjacent one another and form a single row of mosaic elements, each of the first and second mosaic elements being aligned so as to have substantially the same height in a direction perpendicular to the first axis.

20. A solar cell assembly comprising:
a first mosaic element and a second mosaic element each singulated as a quadrant of a circle cut from III-V compound semiconductor circular solar cell wafer;
the first mosaic element being chamfered from a circular wafer along a portion of the wafer's circumferential edge and forming a first straight chamfered edge of the first mosaic element which is sized so as to minimize the loss of usable wafer area; the first mosaic element having a second straight edge having a length equal to the radius of the circular wafer adjacent to the other end of the circumferential edge, and a third straight edge adjacent to and orthogonal to the first straight chamfered edge;
the second mosaic element being chamfered from a circular wafer along a portion of the wafer's circumferential edge and forming a first straight chamfered edge of the first mosaic element which is sized so as to minimize the loss of usable wafer area; the second mosaic element having a second straight edge having a length equal to the radius of the circular wafer adjacent to the other end of the circumferential edge, and a third straight edge adjacent to and orthogonal to the first chamfered edge;
the first and second mosaic elements being arranged directly adjacent to one another along a first axis, so that the first and second curved edges of each of the two mosaic elements are touching and adjacent one another and form a single row of mosaic elements, each of the two mosaic element being aligned so as to have substantially the same height in a direction perpendicular to the first axis, the first mosaic element having a first edge parallel to the first axis and the second mosaic element having a second edge parallel to the first axis, so as to form a substantially rectangular solar cell assembly, with the first edge of the mosaic element forming a portion of one elongated side of the rectangular solar cell assembly, and the second edge of the second mosaic element forming a portion of the opposite elongated side of the rectangular solar cell assembly.
